(19) United States
(12) Patent Application Publication
(10) Pub. No.: US 2023/0013551 A1
(43) Pub. Date: Jan. 19, 2023

(54) PLASMA PROCESSING APPARATUS AND PROCESSING METHOD

(71) Applicant: TOKYO ELECTRON LIMITED, Tokyo (JP)

(72) Inventors: Hiroshi OTOMO, Yamanashi (JP); Takahiro SHINDO, Yamanashi (JP)

(21) Appl. No.: 17/859,520

(22) Filed: Jul. 7, 2022

(30) Foreign Application Priority Data
Jul. 16, 2021 (JP) 2021-118016

(51) Int. Cl. H01J 37/32

(52) U.S. Cl. CPC H01J 37/32577; H01J 37/32091; H01J 37/3244; H01J 37/32128; H01J 37/32183

(57) ABSTRACT

There is provided a plasma processing apparatus comprising: a processing container; a lower electrode provided inside the processing container; an upper electrode disposed to face the lower electrode; a gas supply configured to supply a processing gas between the upper electrode and the lower electrode; a high frequency power source configured to generate plasma of the processing gas by applying a high frequency voltage to the upper electrode; and a voltage waveform shaping part provided between the high frequency power source and the upper electrode and configured to shape a voltage waveform of a high frequency voltage output from the high frequency power source by converting a positive voltage component into a negative voltage component.

### CROSS-REFERENCE TO RELATED APPLICATIONS

This application claims priority to Japanese Patent Application No. 2021-118016 filed on Jul. 16, 2021, the entire contents of which are incorporated herein by reference.

### TECHNICAL FIELD

Exemplary embodiments of the present disclosure relate to a plasma processing apparatus and a processing method.

### BACKGROUND

Plasma processing is often used as processing for substrates such as semiconductor wafers. Japanese Laid-open Patent Publication No. 2017-201611 discloses a technique for reducing the energy of ions irradiated to a chamber body of a plasma processing apparatus by generating an output wave for bias in which a positive voltage component of a high frequency voltage waveform having a fundamental frequency is reduced.

### SUMMARY

The present disclosure provides a technique for reducing energy of ions incident on a lower electrode without increasing the energy of ions incident on an upper electrode.

In accordance with an aspect of the present disclosure, there is provided a plasma processing apparatus comprising: a processing container; a lower electrode provided inside the processing container; an upper electrode disposed to face the lower electrode; a gas supply configured to supply a processing gas between the upper electrode and the lower electrode; a high frequency power source configured to generate plasma of the processing gas by applying a high frequency voltage to the upper electrode; and a voltage waveform shaping part provided between the high frequency power source and the upper electrode and configured to shape a voltage waveform of a high frequency voltage output from the high frequency power source by converting a positive voltage component into a negative voltage component.

### BRIEF DESCRIPTION OF THE DRAWINGS

FIG. 1 is a diagram schematically showing a plasma processing apparatus according to one exemplary embodiment.

FIG. 2 is a diagram showing a configuration of a voltage waveform shaping part according to an example.

FIG. 3 is a diagram for describing the shaping of a voltage applied to an upper electrode.

FIG. 4 is a diagram for describing the shaping of a voltage applied to the upper electrode.

FIG. 5 is a diagram for describing the shaping of a voltage applied to the upper electrode.

FIG. 6 is a diagram showing a configuration of a voltage waveform shaping part according to another example.

FIG. 7 is a diagram showing a configuration of a voltage waveform shaping part according to still another example.

FIG. 8 is a diagram showing a configuration of a voltage waveform shaping part according to yet another example.

FIG. 9 is a diagram showing a configuration of a lower electrode according to another example.

FIG. 10 is a flowchart showing a processing method according to one exemplary embodiment.

### DETAILED DESCRIPTION

Hereinafter, various exemplary embodiments will be described.

In one exemplary embodiment, a plasma processing apparatus is provided. The plasma processing apparatus includes a processing container, a lower electrode, an upper electrode, a gas supply, a high frequency power source, and a voltage waveform shaping part. The lower electrode is provided inside the processing container. The upper electrode is disposed to face the lower electrode. The gas supply is configured to supply a processing gas between the upper electrode and the lower electrode. The high frequency power source is configured to generate plasma of the processing gas by applying a high frequency voltage to the upper electrode. The voltage waveform shaping part is provided between the high frequency power source and the upper electrode and is configured to shape a voltage waveform of the high frequency voltage output from the high frequency power source by converting a positive voltage component into a negative voltage component.

Since shaping of the voltage waveform is performed by full-wave rectification that converts a positive voltage component into a negative voltage component, a peak of the negative voltage component of a shaped voltage applied to the upper electrode is the same as a peak of the negative voltage component of an unshaped voltage (for example, a sinusoidal voltage output by the high frequency power source). For this reason, it is possible to reduce a sheath voltage on the lower electrode while suppressing an increase in a sheath voltage on the upper electrode. Therefore, it is possible to suppress an increase in energy of the ions that impact the upper electrode and to reduce energy of the ions incident on the lower electrode.

In one exemplary embodiment, the plasma processing apparatus further includes a shower head. The shower head introduces the processing gas into the processing container. The shower head is the upper electrode.

In one exemplary embodiment, the plasma processing apparatus further includes a matching device. The matching device is electrically connected between the high frequency power source and the voltage waveform shaping part.

In one exemplary embodiment, the processing gas includes a gas that is used to form a film and provides a raw material for the film to a substrate disposed in the processing container.

In one exemplary embodiment, the voltage waveform shaping part includes a transformer, a first rectifier, and a second rectifier. The transformer has a primary coil and a secondary coil. The high frequency power source is electrically connected between two terminals of the primary coil. The secondary coil has two coils connected in series. Each of two terminals of the secondary coil is electrically connected to a cathode of the first rectifier and a cathode of the second rectifier, respectively. A connection node between the two coils of the secondary coil is electrically grounded. An anode of the first rectifier and an anode of the second rectifier are electrically connected to the upper electrode.

In one exemplary embodiment, the voltage waveform shaping part includes the transformer and a diode bridge circuit. The transformer has the primary coil and the secondary coil. The high frequency power source is electrically connected between the two terminals of the primary coil. The diode bridge circuit has a first rectifier, a second rectifier, a third rectifier, and a fourth rectifier. A cathode of the first rectifier is electrically connected to an anode of the second rectifier. An anode of the first rectifier is electrically connected to an anode of the third rectifier. A cathode of the second rectifier is electrically connected to a cathode of the fourth rectifier. A cathode of the third rectifier is electrically connected to an anode of the fourth rectifier. The cathode of the first rectifier is electrically connected to the cathode of the third rectifier via the secondary coil. The anode of the first rectifier and the anode of the third rectifier are electrically connected to the upper electrode. The cathode of the second rectifier and the cathode of the fourth rectifier are electrically grounded.

In one exemplary embodiment, the voltage waveform shaping part includes the diode bridge circuit. The diode bridge circuit has the first rectifier, the second rectifier, the third rectifier, and the fourth rectifier. The cathode of the first rectifier is electrically connected to the anode of the second rectifier. The anode of the first rectifier is electrically connected to the anode of the third rectifier. The cathode of the second rectifier is electrically connected to the cathode of the fourth rectifier. The cathode of the third rectifier is electrically connected to the anode of the fourth rectifier. Each of two terminals of the high frequency power source is electrically connected to the cathode of the first rectifier and the cathode of the third rectifier, respectively. The anode of the first rectifier and the anode of the third rectifier are electrically connected to the upper electrode. The cathode of the second rectifier and the cathode of the fourth rectifier are electrically connected to the lower electrode.

In one exemplary embodiment, the voltage waveform shaping part includes the transformer, a first switching element, and a second switching element. The transformer has the primary coil and the secondary coil. The high frequency power source is electrically connected between the two terminals of the primary coil. The secondary coil has the two coils connected in series. Each of the two terminals of the secondary coil is electrically connected to the first switching element and the second switching element, respectively. The connection node between the two coils of the secondary coil is electrically grounded. Each of the two terminals of the secondary coil is electrically connected to the upper electrode via each of the first switching element and the second switching element. The first switching element and the second switching element are configured to cut off a current flowing from the secondary coil.

In one exemplary embodiment, the plasma processing apparatus further includes a substrate mounting table. The substrate mounting table is provided inside the processing container, and the substrate is mounted thereon. The substrate mounting table is the lower electrode and is an electrically grounded conductor.

In one exemplary embodiment, the plasma processing apparatus further includes the substrate mounting table and a ground electrode. The substrate mounting table is provided inside the processing container, and the substrate is mounted thereon. The ground electrode is provided outside the substrate mounting table. A raw material for the substrate mounting table is an insulator. The ground electrode is the lower electrode and is an electrically grounded conductor.

In one exemplary embodiment, the raw material for the substrate mounting table is a ceramic.

In another exemplary embodiment, a processing method is provided. The processing method is a processing method in which plasma processing is performed on a substrate disposed inside the processing container of the plasma processing apparatus. The processing method includes Steps a, b, and c. In Step a, a processing gas is supplied between the upper electrode and the lower electrode of the plasma processing apparatus. In Step b, a voltage waveform of a high frequency voltage output from the high frequency power source of the plasma processing apparatus is shaped by converting a positive voltage component into a negative voltage component. In Step c, a high frequency voltage after shaping is applied to the upper electrode. The processing gas includes a gas that is used for forming a film and provides a raw material for the film to the substrate.

Since the shaping of the voltage waveform is performed by full-wave rectification that converts the positive voltage component into the negative voltage component, a peak of a negative voltage component of a shaped voltage applied to the upper electrode is the same as a peak of a negative voltage component of an unshaped voltage (for example, a sinusoidal voltage output by the high frequency power source). For this reason, it is possible to suppress an increase in a sheath voltage on the upper electrode and to reduce a sheath voltage on the lower electrode. Therefore, it is possible to suppress the increase in energy of the ions that impact the upper electrode and to reduce energy of the ions incident on the lower electrode.

Hereinafter, various exemplary embodiments will be described in detail with reference to the accompanying drawings. In addition, the same reference numerals are given to the same or corresponding parts in each of the drawings.

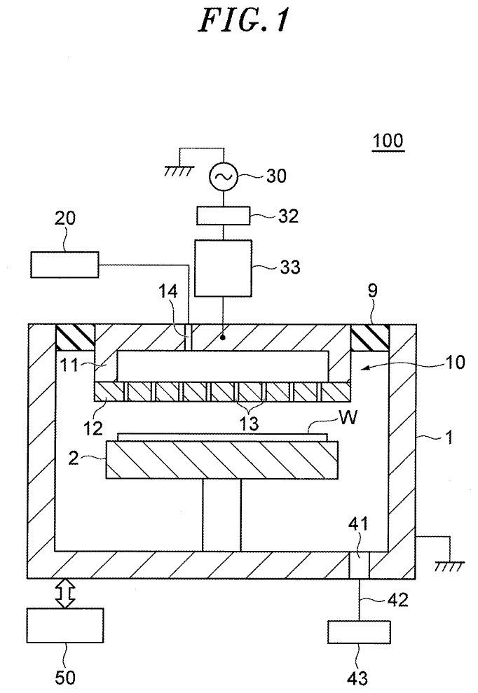

FIG. 1 is a diagram schematically showing a plasma processing apparatus according to one exemplary embodiment. The plasma processing apparatus 100 shown in FIG. 1 performs plasma processing on a substrate W. The plasma processing apparatus 100 may be a capacitively coupled plasma processing apparatus. Examples of the substrate W include semiconductor wafers, but the present disclosure is not limited thereto.

The plasma processing apparatus 100 has a processing container 1 formed of a metal and having a substantially cylindrical shape. The processing container 1 is electrically grounded. A substrate mounting table 2 for horizontally mounting the substrate W is provided inside the processing container 1. The substrate mounting table 2 includes an electrically grounded lower electrode. The lower electrode is provided inside the processing container 1. The substrate mounting table 2 shown in FIG. 1 is an electrically grounded conductor and is a lower electrode.

The substrate mounting table 2 may have a heating mechanism or a cooling mechanism depending on the plasma processing. A plurality of lifting pins (not shown) are inserted through the substrate mounting table 2 so as to be able to protrude and retract with respect to an upper surface of the substrate mounting table 2. The substrate W is transferred to or from the substrate mounting table 2 by a lifting operation of the plurality of lifting pins by a lifting mechanism (not shown).

An opening is provided in an upper portion of the processing container 1, and the shower head 10 is fitted into the opening via an insulating member 9 so as to face the substrate mounting table 2 which is a lower electrode (hereinafter, simply referred to as the substrate mounting table 2). The shower head 10 is a conductor. The shower head 10 may be an upper electrode to which a high frequency voltage is applied from a high frequency power source 30. The overall shape of the shower head 10, which is an upper electrode (hereinafter, simply referred to as the shower head 10), may be cylindrical. The shower head 10 has a main body 11 having an opening at a lower portion thereof, and a shower plate 12 provided to close the opening of the main body 11. An internal space between the main body 11 and the shower plate 12 provides a gas diffusion space. A plurality of gas discharge holes 13 are provided in the shower plate 12.

A gas introduction hole 14 is provided in the shower head 10, and the processing gas for plasma processing supplied from a gas supply 20 is introduced into the shower head 10 through the gas introduction hole 14.

The gas supply 20 is configured to supply the processing gas between the shower head 10 and the substrate mounting table 2. The processing gas introduced into the shower head 10 is introduced into the processing container 1 through the gas discharge hole 13 and is supplied to a space between the shower head 10 and the substrate mounting table 2.

The gas supply 20 supplies a plurality of gases including a processing gas, a plasma generating gas, and a purge gas that are required for plasma processing. As the processing gas, an appropriate gas is selected depending on the plasma processing to be performed. For example, the processing gas may include a gas which is used to form a film and provides a raw material for the film to the substrate W. The gas supply 20 has a plurality of gas supply sources and gas supply pipes, and a flow rate controller such as valves and a mass flow controller may be provided in each of the gas supply pipes.

The high frequency power source 30 is electrically connected to the shower head 10. The high frequency power source 30 is configured to output a high frequency voltage of 10 kHz to 60 MHz. Capacitively coupled plasma is generated between the shower head 10 and the substrate mounting table 2 by applying a high frequency voltage from the high frequency power source 30 to the shower head 10.

A matching device 32 is electrically connected between the high frequency power source 30 and a voltage waveform shaping part 33. The matching device 32 is configured to match a load impedance with an internal impedance (or an output impedance) of the high frequency power source 30.

The voltage waveform shaping part 33 is electrically connected between the matching device 32 and the shower head 10. The voltage waveform shaping part 33 is a full-wave rectifier configured to shape a voltage waveform of the high frequency voltage output from the high frequency power source 30 by converting a positive voltage component into a negative voltage component.

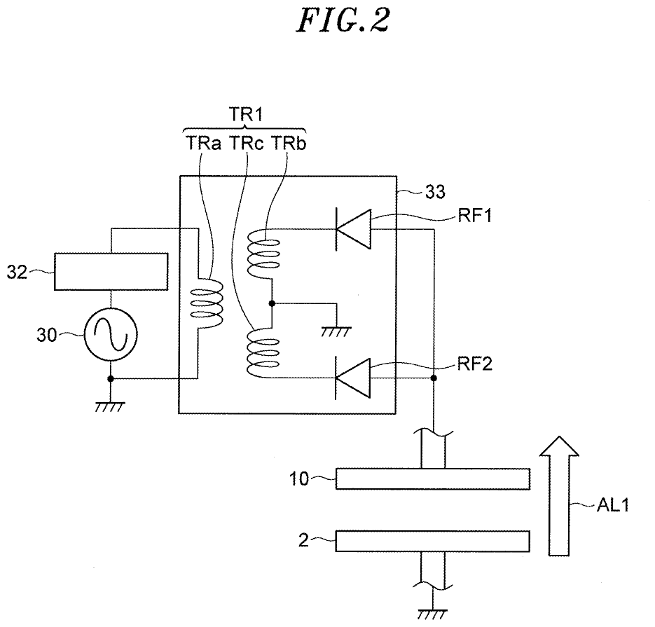

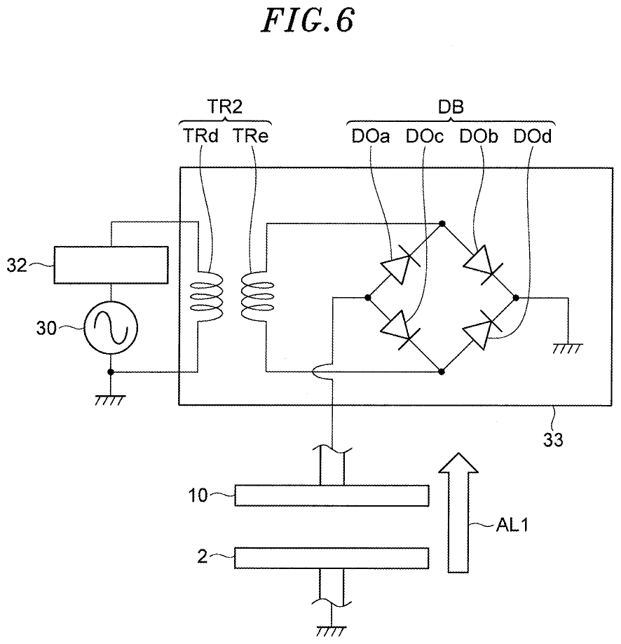

An example of a configuration of the voltage waveform shaping part 33 is shown in FIG. 2. In addition, FIGS. 6 to 9 show another configuration examples of the voltage waveform shaping part 33.

As shown in FIG. 2, the voltage waveform shaping part 33 includes a transformer TR1, a rectifier RF1, and a rectifier RF2. The transformer TR1 has a primary coil and a secondary coil. The primary coil has a coil TRa. The secondary coil has a coil TRb and a coil TRc. The high frequency power source 30 is electrically connected between two terminals of the coil TRa. The two coils (the coil TRb and the coil TRc) of the secondary coil are connected in series. Each of two terminals of the secondary coil is electrically connected to a cathode of the rectifier RF1 and a cathode of the rectifier RF2, respectively. In other words, the coil TRb included in the secondary coil is electrically connected to the cathode of the rectifier RF1, and the coil TRc included in the secondary coil is electrically connected to the cathode of the rectifier RF2. A connection node between the coil TRb and the coil TRc is electrically grounded. An anode of the rectifier RF1 and an anode of the rectifier RF2 are electrically connected to the shower head 10.

When the voltage waveform shaping part 33 shown in FIG. 2 is used, the high frequency voltage output from the high frequency power source 30 is full-wave rectified by the voltage waveform shaping part 33 in a state in which plasma is generated. A current flowing between the substrate mounting table 2 and the shower head 10 is a DC current flowing only in a discharge path in a direction AL1 from the substrate mounting table 2 to the shower head 10. The direction AL1 indicates a direction from the substrate mounting table 2 toward the shower head 10. The same applies to a case in which the voltage waveform shaping part 33 exemplified in each of FIGS. 6, 7, and 8 is used.

Returning to FIG. 1, an exhaust port 41 is provided in a bottom wall of the processing container 1, and an exhaust device 43 is connected to the exhaust port 41 via an exhaust pipe 42. The exhaust device 43 has an automatic pressure control valve and a vacuum pump. By the exhaust device 43, the inside of the processing container 1 can be exhausted and the inside of the processing container 1 can be maintained at a preset degree of vacuum.

Although not shown, a loading and unloading port for loading and unloading the substrate W into/from the processing container 1 is provided in a side wall of the processing container 1. The loading and unloading port is configured to be opened or closed by a gate valve.

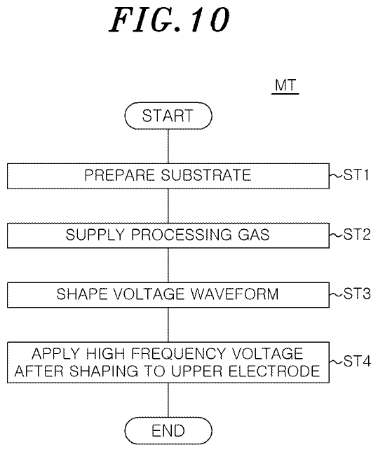

The valves and flow rate controller of the gas supply 20, the high frequency power source, and the like are controlled by a controller 50. The controller 50 includes a main controller having a central processing unit (CPU), an input device, an output device, a display device, and a memory device. Various processes performed by the plasma processing apparatus 100 are controlled based on a processing recipe stored in a memory medium of the memory device. In particular, the controller 50 performs each step of a processing method MT exemplified in FIG. 10 by controlling each component of the plasma processing apparatus 100.

Next, with reference to FIG. 10, the processing method MT for performing plasma processing on the substrate W disposed inside the processing container 1 of the plasma processing apparatus 100 will be described. First, a gate valve is opened, the substrate W is loaded into the processing container 1 through the loading and unloading port by a transport device (not shown), and the substrate W is mounted on the substrate mounting table 2 to prepare the substrate W (Step ST1). After the transport device is retracted, the gate valve is closed.

In Step ST2 which is performed after Step ST1, a pressure of the processing container 1 is adjusted, and then the processing gas is supplied between the upper electrode (for example, the shower head 10) and the lower electrode (for example, the substrate mounting table 2) of the plasma processing apparatus 100 (Step ST2).

Step ST3 is performed after or in conjunction with Step ST2. In Step ST3, the voltage waveform of the high frequency voltage output from the high frequency power source 30 is shaped by converting the positive voltage component into the negative voltage component (Step ST3).

In Step ST4 which is performed after Step ST3, the high frequency voltage after shaping is applied to the upper electrode.

Therefore, a high frequency electric field is formed between the shower head 10 and the substrate mounting table 2 to generate capacitively coupled plasma.

In a general capacitively coupled plasma processing apparatus, when the lower electrode is electrically grounded, a plasma potential greatly depends on the potential of the upper electrode. The plasma potential was α V at the moment when the upper electrode was 0 V, but the plasma potential can be about 100+α V at the moment when the upper electrode is 100 V. The ions in the plasma are accelerated by a sheath voltage (a difference between the plasma potential and the substrate potential) on the surface of the substrate and are introduced into the substrate. In order to increase input power to the plasma, it is conceivable to increase the amplitude of a sinusoidal high frequency voltage output by the high frequency power source. In this case, the plasma potential is increased by a positive side portion of the high frequency voltage output by the high frequency power source, and the sheath voltage becomes high. As a result, an acceleration of the ions toward the substrate W becomes large, and ion impact on the substrate W may be strong.

On the other hand, in the plasma processing apparatus 100 described above, the voltage waveform shaping part 33 is provided on the downstream side of the matching device 32. The voltage waveform shaping part 33 performs the full-wave rectification that shapes the voltage waveform of the high frequency voltage output from the high frequency power source 30 by converting the positive voltage component into the negative voltage component. Due to the full-wave rectification by the voltage waveform shaping part 33, a positive voltage component becomes a negative voltage component in the high frequency voltage applied to the shower head 10. In this case, a peak of the negative voltage component of a shaped voltage applied to the shower head 10 is the same as a peak of the negative voltage component of an unshaped voltage (for example, a sinusoidal voltage output by the high frequency power source 30). For this reason, particularly, the increase in energy that the ions in the plasma impact the shower head 10 is suppressed, and the energy that the ions in the plasma impact the substrate mounting table 2 and the substrate W is reduced.

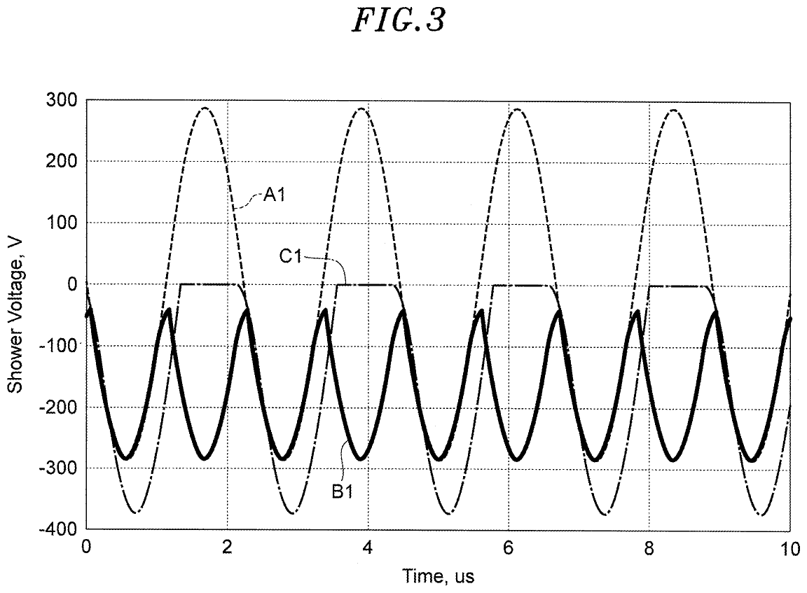

With reference to FIGS. 3, 4, and 5, an effect of the shaping by full-wave rectification of the high frequency voltage applied to the shower head 10 will be described. The following description is the same in the configurations shown in each of FIGS. 2 and 6 to 9.

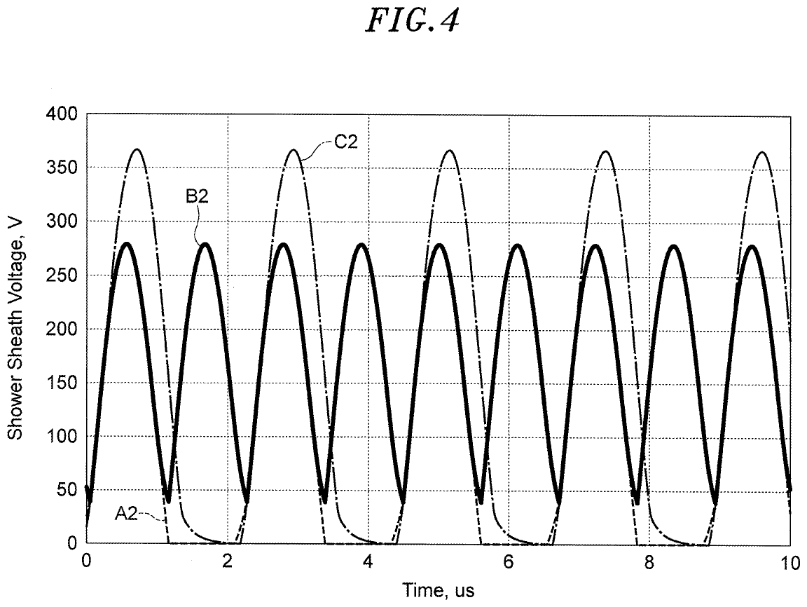

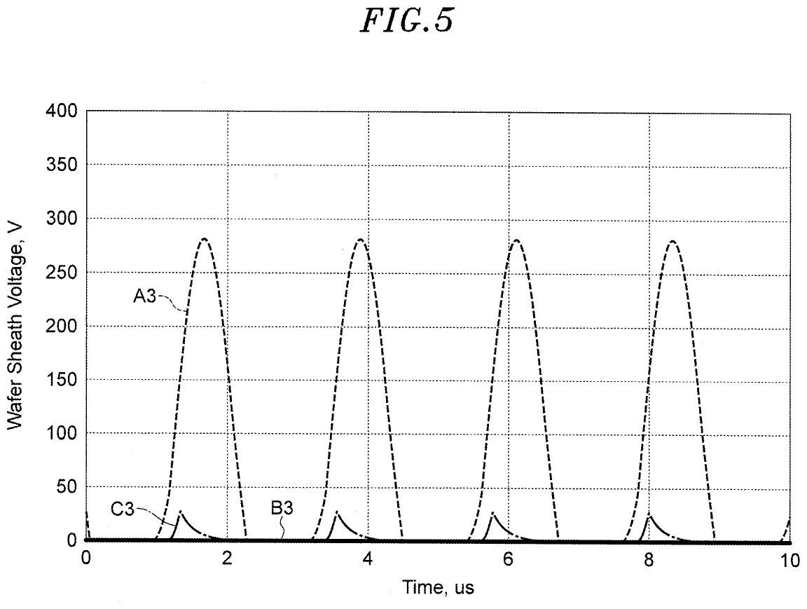

Horizontal axes shown in FIGS. 3, 4, and 5 all represent time (μs). A vertical axis of FIG. 3 represents a voltage (V) applied to the shower head 10. A vertical axis of FIG. 4 represents a first sheath voltage (V) formed on the surface of the shower head 10. A vertical axis of FIG. 5 represents a second sheath voltage (V) formed on the surface of the substrate W. The results shown in FIGS. 3 to 5 are obtained by simulation.

A waveform A1, a waveform A2, and a waveform A3 represent voltage waveforms when a sinusoidal high frequency voltage output from the high frequency power source 30 which is not shaped by full-wave rectification is applied to the shower head 10, respectively. A waveform B1, a waveform B2, and a waveform B3 represent voltage waveforms of the high frequency voltage after the shaping the sinusoidal high frequency voltage output from the high frequency power source 30 by full-wave rectification in the voltage waveform shaping part 33, respectively. A waveform C1, a waveform C2, and a waveform C3 represent voltage waveforms of the high frequency voltage after shaping the sinusoidal high frequency voltage output from the high frequency power source 30 by half-wave rectification, respectively.

Referring to FIG. 3, it can be seen that the peak of the negative voltage component of the high frequency voltage (the waveform B1) after the shaping by full-wave rectification is the same as the peak of the negative voltage component of the sinusoidal high frequency voltage (the waveform A1). On the other hand, it can be seen that the peak of the negative voltage component of the high frequency voltage (the waveform B1) after the shaping by full-wave rectification is smaller than the peak of the negative voltage component of the high frequency voltage (the waveform C1) after shaping by half-wave rectification.

Further, referring to FIG. 4, it can be seen that the peak of the first sheath voltage (the waveform B2) when the high frequency voltage of the waveform B1 after the shaping by full-wave rectification is applied to the shower head 10 is the same as the peak of the first sheath voltage (the waveform A2) when the high frequency voltage of the waveform A1 is applied to the shower head 10. On the other hand, it can be seen that the peak of the first sheath voltage of the waveform B2 is lower than the peak of the first sheath voltage (the waveform C2) when the high frequency voltage (the waveform C1) after the shaping by half-wave rectification is applied to the shower head 10.

Further, referring to FIG. 5, it can be seen that the peak of the second sheath voltage (the waveform B3) when the high frequency voltage of the waveform B1 after the shaping by full-wave rectification is applied to the shower head 10 is lower than the peak of the second sheath voltage (the waveform A3) when the high frequency voltage of the waveform A1 is applied to the shower head 10. On the other hand, it can be seen that the peak of the second sheath voltage of the waveform B3 is lower than the peak of the second sheath voltage (the waveform C3) when the high frequency voltage (the waveform C1) after the shaping by half-wave rectification is applied to the shower head 10.

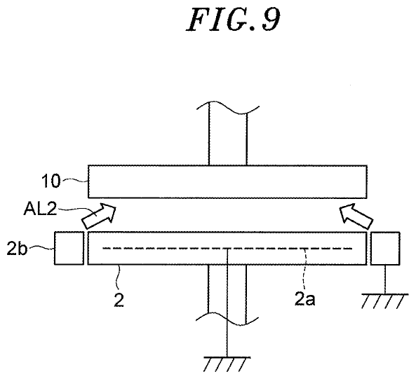

In this way, the sinusoidal high frequency voltage output from the high frequency power source 30 is full-wave rectified by the voltage waveform shaping part 33 and then is applied to the shower head 10. Thus, it is possible to suppress an increase in the sheath voltage on the upper electrode (specifically, on the surface of the shower head 10) and to reduce the sheath voltage on the lower electrode (specifically, on the surface of the substrate mounting table 2 and the substrate W). Therefore, it is possible to suppress the increase in energy of the ions that impact the upper electrode (the shower head 10) and to reduce energy of the ions incident on the lower electrode (the substrate mounting table 2 and the substrate W). The above description is the same not only when the voltage waveform shaping part 33 of FIG. 2 is used, but also when each voltage waveform shaping part 33 of FIGS. 6 to 8 is used, and is also the same when the substrate mounting table 2 and a ground electrode 2b of FIG. 9 are used.

FIG. 6 shows another configuration example of the voltage waveform shaping part 33. The voltage waveform shaping part 33 shown in FIG. 6 has a transformer TR2 and a diode bridge circuit DB. The transformer TR2 has a primary coil and a secondary coil.

The primary coil has a coil TRd. The high frequency power source 30 is electrically connected between two terminals of the coil TRd. The secondary coil has a coil TRe. The diode bridge circuit DB is electrically connected between two terminals of the coil TRe.

The diode bridge circuit DB includes a rectifier DOa, a rectifier DOb, a rectifier DOc, and a rectifier DOd. A cathode of the rectifier DOa is electrically connected to an anode of the rectifier DOb. An anode of the rectifier DOa is electrically connected to an anode of the rectifier DOc. A cathode of the rectifier DOb is electrically connected to a cathode of the rectifier DOd. A cathode of the rectifier DOc is electrically connected to an anode of the rectifier DOd.

The cathode of the rectifier DOa and the anode of the rectifier DOb are electrically connected to the cathode of the rectifier DOc and the anode of the rectifier DOd via the coil TRe. The anode of the rectifier DOa and the anode of the rectifier DOc are electrically connected to the shower head 10. The cathode of the rectifier DOb and the cathode of the rectifier DOd are electrically grounded.

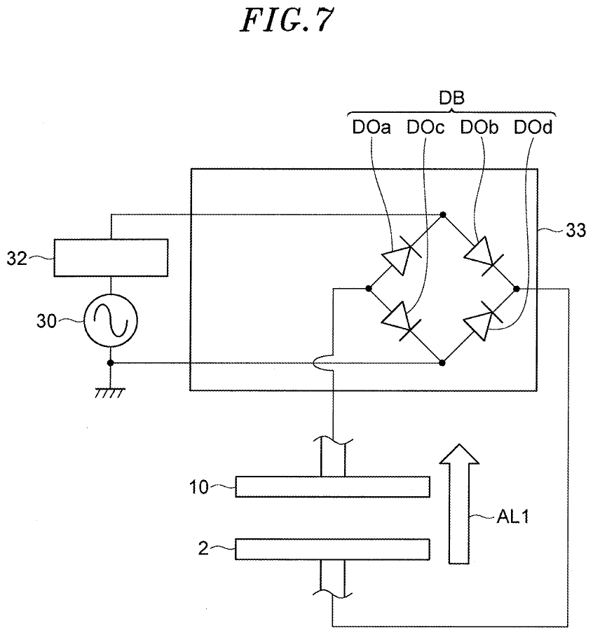

FIG. 7 shows still another configuration example of the voltage waveform shaping part 33. The voltage waveform shaping part 33 shown in FIG. 7 has a diode bridge circuit DB. The diode bridge circuit DB includes a rectifier DOa, a rectifier DOb, a rectifier DOc, and a rectifier DOd. A cathode of the rectifier DOa is electrically connected to an anode of the rectifier DOb. An anode of the rectifier DOa is electrically connected to an anode of the rectifier DOc. A cathode of the rectifier DOb is electrically connected to a cathode of the rectifier DOd. A cathode of the rectifier DOc is electrically connected to an anode of the rectifier DOd. Each of two terminals of the high frequency power source 30 is electrically connected to the cathode of the rectifier DOa and the cathode of the rectifier Doc, respectively. In other words, each of the two terminals of the high frequency power source 30 is electrically connected to the anode of the rectifier DOb and the anode of the rectifier DOd, respectively. The anode of the rectifier DOa and the anode of the rectifier DOc are electrically connected to the shower head 10. The cathode of the rectifier DOb and the cathode of the rectifier DOd are electrically connected to the substrate mounting table 2.

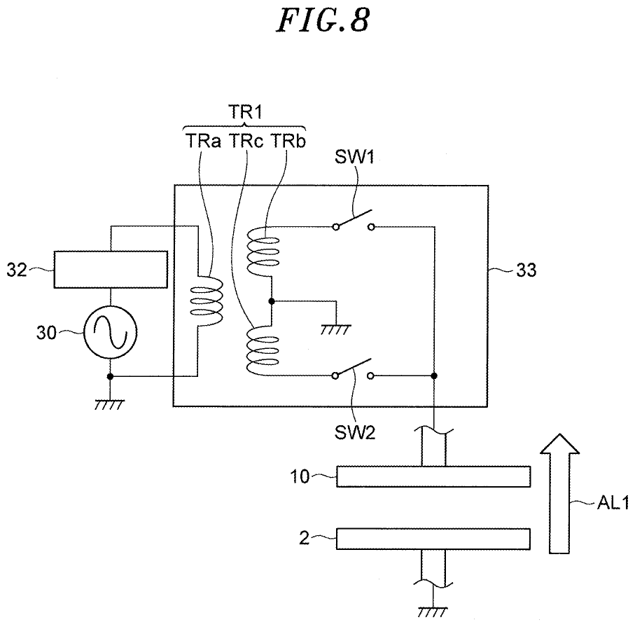

FIG. 8 shows yet another configuration example of the voltage waveform shaping part 33. The voltage waveform shaping part 33 shown in FIG. 8 has a transformer TR1, a switching element SW1, and a switching element SW2. The transformer TR1 has a primary coil and a secondary coil. The primary coil has a coil TRa. The secondary coil has a coil TRb and a coil TRc. The high frequency power source 30 is electrically connected between two terminals of the coil TRa. The two coils (the coil TRb and the coil TRc) of the secondary coil are connected in series. Each of two terminals of the secondary coil is electrically connected to the switching element SW1 and the switching element SW2, respectively. In other words, the coil TRb included in the secondary coil is electrically connected to the switching element SW1, and the coil TRc included in the secondary coil is electrically connected to the switching element SW2. A connection node between the coil TRb and the coil TRc is electrically grounded. The switching element SW1 and the switching element SW2 are electrically connected to the shower head 10. Each of the two terminals of the secondary coil is electrically connected to the shower head 10 via the switching element SW1 and the switching element SW2, respectively.

The switching element SW1 and the switching element SW2 may be field effect transistors (FETs) or the like. The switching element SW1 and the switching element SW2 are configured to cut off a current flowing from the secondary coil.

Although various exemplary embodiments have been described above, various omissions, substitutions, and changes may be made without being limited to the above-mentioned exemplary embodiments. It is also possible to combine elements from different exemplary embodiments to form other exemplary embodiments.

For example, it is conceivable that the substrate mounting table has a raw material other than the conductor. The raw material of the substrate mounting table 2 shown in FIG. 9 is an insulator such as a ceramic and may be, for example, AN or the like. The substrate mounting table 2 includes an electrically grounded electrostatic chuck 2a. The ground electrode 2b is provided outside the substrate mounting table 2. The ground electrode 2b is electrically grounded. The ground electrode 2b, for example, may be disposed to surround the substrate mounting table 2. When the high frequency voltage output from the high frequency power source 30 is full-wave rectified by the voltage waveform shaping part 33 in a state in which plasma is generated, the current is a DC current that flows only in a discharge path in a direction AL1 (FIG. 2 and the like) from the substrate mounting table 2 toward the shower head 10. For this reason, when an insulator is present in the discharge path in the direction AL1, no DC current flows in the discharge path in the direction AL1. On the other hand, when the ground electrode 2b is provided outside the substrate mounting table 2 formed of an insulator, a new discharge path in a direction AL2 which avoids the substrate mounting table 2 can be formed. The direction AL2 indicates a direction from the ground electrode 2b toward the shower head 10. Therefore, even the substrate mounting table 2 is formed of an insulator, a DC current can flow in the direction AL2 from the ground electrode 2b toward the shower head 10 in the state in which plasma is generated.

From the above description, it will be appreciated that the various exemplary embodiments of the present disclosure have been described herein for purposes of description and that various modifications may be made without departing from the scope and gist of the present disclosure. Accordingly, the various exemplary embodiments disclosed herein are not intended to be limiting, and the true scope and spirit of the present disclosure is set forth by the appended claims.

What is claimed is:

1. A plasma processing apparatus comprising:
a processing container;
a lower electrode provided inside the processing container;
an upper electrode disposed to face the lower electrode;
a gas supply configured to supply a processing gas between the upper electrode and the lower electrode;
a high frequency power source configured to generate plasma of the processing gas by applying a high frequency voltage to the upper electrode; and
a voltage waveform shaping part provided between the high frequency power source and the upper electrode and configured to shape a voltage waveform of a high frequency voltage output from the high frequency power source by converting a positive voltage component into a negative voltage component.

2. The plasma processing apparatus of claim 1, further comprising a shower head that introduces the processing gas into the processing container,
wherein the shower head is the upper electrode.

3. The plasma processing apparatus of claim 1, further comprising a matching device electrically connected between the high frequency power source and the voltage waveform shaping part.

4. The plasma processing apparatus of claim 1, wherein the processing gas contains a gas which is used for forming a film and provides a raw material for the film to a substrate disposed in the processing container.

5. The plasma processing apparatus of claim 1, wherein the voltage waveform shaping part includes a transformer, a first rectifier, and a second rectifier,
the transformer has a primary coil and a secondary coil,
the high frequency power source is electrically connected between two terminals of the primary coil,
the secondary coil has two coils connected in series,
each of two terminals of the secondary coil is electrically connected to a cathode of the first rectifier and a cathode of the second rectifier, respectively,
a connection node between the two coils of the secondary coil is electrically grounded, and
an anode of the first rectifier and an anode of the second rectifier are electrically connected to the upper electrode.

6. The plasma processing apparatus of claim 1, wherein the voltage waveform shaping part includes a transformer and a diode bridge circuit,
the transformer has a primary coil and a secondary coil,
the high frequency power source is electrically connected between two terminals of the primary coil,
the diode bridge circuit includes a first rectifier, a second rectifier, a third rectifier, and a fourth rectifier,
a cathode of the first rectifier is electrically connected to an anode of the second rectifier,
an anode of the first rectifier is electrically connected to an anode of the third rectifier,
a cathode of the second rectifier is electrically connected to a cathode of the fourth rectifier,
a cathode of the third rectifier is electrically connected to an anode of the fourth rectifier,
the cathode of the first rectifier is electrically connected to the cathode of the third rectifier via the secondary coil,
the anode of the first rectifier and the anode of the third rectifier are electrically connected to the upper electrode, and
the cathode of the second rectifier and the cathode of the fourth rectifier are electrically grounded.

7. The plasma processing apparatus of claim 1, wherein the voltage waveform shaping part has a diode bridge circuit,
the diode bridge circuit has a first rectifier, a second rectifier, a third rectifier, and a fourth rectifier,
a cathode of the first rectifier is electrically connected to an anode of the second rectifier,
an anode of the first rectifier is electrically connected to an anode of the third rectifier,
a cathode of the second rectifier is electrically connected to a cathode of the fourth rectifier,
a cathode of the third rectifier is electrically connected to an anode of the fourth rectifier,
each of two terminals of the high frequency power source is electrically connected to the cathode of the first rectifier and the cathode of the third rectifier, respectively,
the anode of the first rectifier and the anode of the third rectifier are electrically connected to the upper electrode, and
the cathode of the second rectifier and the cathode of the fourth rectifier are electrically connected to the lower electrode.

8. The plasma processing apparatus of claim 1, wherein the voltage waveform shaping part includes a transformer, a first switching element, and a second switching element,
the transformer has a primary coil and a secondary coil,
the high frequency power source is electrically connected between two terminals of the primary coil,
the secondary coil has two coils connected in series,
each of two terminals of the secondary coil is electrically connected to the first switching element and the second switching element, respectively,
a connection node between the two coils of the secondary coil is electrically grounded,
each of the two terminals of the secondary coil is electrically connected to the upper electrode via each of the first switching element and the second switching element, and
the first switching element and the second switching element are configured to cut off a current flowing from the secondary coil.

9. The plasma processing apparatus of claim 1, further comprising a substrate mounting table provided inside the processing container and configured to allow a substrate to be mounted thereon,
wherein the substrate mounting table is the lower electrode and is an electrically grounded conductor.

10. The plasma processing apparatus of claim 1, further comprising:
a substrate mounting table provided inside the processing container and configured to allow a substrate to be mounted thereon; and
a ground electrode provided outside the substrate mounting table,
wherein a raw material of the substrate mounting table is an insulator, and
the ground electrode is the lower electrode and is an electrically grounded conductor.

11. The plasma processing apparatus of claim 10, wherein the raw material of the substrate mounting table is a ceramic.

12. A processing method that performs plasma processing on a substrate disposed inside a processing container of a plasma processing apparatus, the method comprising:
supplying a processing gas between an upper electrode and a lower electrode of the plasma processing apparatus;
shaping a voltage waveform of a high frequency voltage output from a high frequency power source of the plasma processing apparatus by converting a positive voltage component into a negative voltage component; and
applying the high frequency voltage after the shaping to the upper electrode,
wherein the processing gas contains a gas which is used for forming a film and provides a raw material for the film to the substrate.
